(19) United States
(12) Patent Application Publication
(10) Pub. No.: US 2017/0236884 A1
(43) Pub. Date: Aug. 17, 2017

(54) FLAT PANEL AND FLAT PANEL DISPLAY

(71) Applicant: Shenzhen China Star Optoelectronics Technology Co., Ltd., Shenzhen, Guangdong (CN)

(72) Inventor: Jiang ZHU, Shenzhen, Guangdong (CN)

(73) Assignee: Shenzhen China Star Optoelectronics Technology Co., Ltd., Shenzhen, Guangdong (CN)

(21) Appl. No.: 14/902,555

(22) PCT Filed: Sep. 24, 2015
(86) PCT No.: PCT/CN2015/090533

§ 371 Date: Dec. 31, 2015

(30) Foreign Application Priority Data
Sep. 7, 2015 (CN) 201510565794.0

(51) Int. Cl. H01L 27/32; G02F 1/155; G02F 1/1343; G02F 1/163

(52) U.S. Cl. CPC H01L 27/3232; G02F 1/163; G02F 1/155; G02F 1/13439; H01L 27/322; G02F 2201/121; G02F 2001/1504

(57) ABSTRACT

The present invention discloses a flat panel and a flat panel display. The flat panel comprises a plurality of pixels, and in each pixel: the first ion transport layer and the first transparent electrode layer respectively generate a first hole and a first electron, and the organic light emitting layer generates white light; the second ion transport layer and the second transparent electrode layer respectively generate a second hole and a second electron, and the electrochromic layer changes color; a value of the second voltage is adjusted to make the electrochromic layer change to be three colors of red, green, blue, and to correspondingly generate red light, green light and blue light with the white light generated by the organic light emitting layer, and the generated red light, green light and blue light are color mixed to be kinds of colors.

### CROSS REFERENCE

This application claims the priority of Chinese Patent Application No. 201510565794.0, entitled “Flat panel and flat panel display”, filed on Sep. 7, 2015, the disclosure of which is incorporated herein by reference in its entirety.

### FIELD OF THE INVENTION

The present invention relates to an electronic technology field, and more particularly to a flat panel and a flat panel display.

### BACKGROUND OF THE INVENTION

With the development of the economics and the technology, the flat panel display of high resolution becomes more and more popular. As shown in FIG. 1, one pixel dot in the traditional flat panel display is consisted of three sub pixels, the red sub pixel, the green sub pixel and the blue sub pixel. According to the principle of spatial mixed color, the three primary colors generated by the red sub pixel, the green sub pixel and the blue sub pixel are mixed to be kinds of colors which are required. Therefore, for the flat panel display of resolution X, it is actually required to use the sub pixel dots of amount 3X for achieving the effect of resolution X. Each sub pixel must occupy a certain area. The more the sub pixels are, the more the occupied area becomes. The manufacture will be more difficult when the area of the flat panel display becomes larger.

### SUMMARY OF THE INVENTION

The technical issue that the embodiment of the present invention solves is to provide a flat panel and flat panel display, achieving the resolution increase of the flat panel display in the same area.

The present invention provides a flat panel, comprising an electrochromic element and an organic electrochromic element, and the electrochromic element is located on the organic electrochromic element; a first substrate for supporting, a first transparent electrode layer, a first ion transport layer, an organic light emitting layer, a first electron transport layer, a common electrode layer, which are sequentially stacked up to compose the organic electrochromic element; the common electrode layer, a second electron transport layer, an electrochromic layer, a second ion transport layer, a second transparent electrode layer and a second substrate for supporting, which are sequentially stacked up to compose the electrochromic element; the flat panel comprises a plurality of pixels, and in each pixel: a first voltage is applied between the first transparent electrode layer and the common electrode layer, and the first transparent electrode layer transmits the first voltage to the first ion transport layer, and the common electrode layer transmits the first voltage to the first electron transport layer, and the first ion transport layer and the first transparent electrode layer respectively transmit a first hole and a first electron under function of the first voltage, and the organic light emitting layer generates white light under function of the first hole and the first electron; a second voltage is applied between the second transparent electrode layer and the common electrode layer, and the second transparent electrode layer transmits the second voltage to the second ion transport layer, and the common electrode layer transmits the second voltage to the second electron transport layer, and the second ion transport layer and the second transparent electrode layer respectively transmit a second hole and a second electron under function of the second voltage, and the electrochromic layer changes color under function of the second hole and the second electron; a value of the second voltage is adjusted to make the electrochromic layer change to be three colors of red, green, blue at different times, and to correspondingly generate red light, green light and blue light with the white light generated by the organic light emitting layer, and the generated red light, green light and blue light are color mixed to be kinds of colors.

Selectively, when a brightness is required to be increased, a time ratio of generating the red light, green light and blue light is unchanged, and light emitting periods of generating the red light, green light and blue light are increased, and when brightness is required to be decreased, the time ratio of generating the red light, green light and blue light is unchanged, and the light emitting periods of generating the red light, green light and blue light are decreased.

Selectively, what the electrochromic layer utilizes is a combination of any one or more of Polythiophene and derivatives thereof, viologen, Tetrathiafulvalene, metallophthalocyanine.

Selectively, the electrochromic layer is formed by any one of etching, deposition, vapor deposition.

Selectively, material of the organic light emitting layer is a combination of any one or more of Polyvinylcarbazole, polyfluorene, Polyphenylene vinylene and Polythiophene.

The present invention further provides a flat panel display, comprising a flat panel and a base plate, and the flat panel comprises an electrochromic element and an organic electrochromic element, and the electrochromic element is located on the organic electrochromic element; a first substrate for supporting, a first transparent electrode layer, a first ion transport layer, an organic light emitting layer, a first electron transport layer, a common electrode layer, which are sequentially stacked up to compose the organic electrochromic element; the common electrode layer, a second electron transport layer, an electrochromic layer, a second ion transport layer, a second transparent electrode layer and a second substrate for supporting, which are sequentially stacked up to compose the electrochromic element; the flat panel display comprises a plurality of pixels, and in each pixel: a first voltage is applied between the first transparent electrode layer and the common electrode layer, and the first transparent electrode layer transmits the first voltage to the first ion transport layer, and the common electrode layer transmits the first voltage to the first electron transport layer, and the first ion transport layer and the first transparent electrode layer respectively transmit a first hole and a first electron under function of the first voltage, and the organic light emitting layer generates white light under function of the first hole and the first electron; a second voltage is applied between the second transparent electrode layer and the common electrode layer, and the second transparent electrode layer transmits the second voltage to the second ion transport layer, and the common electrode layer transmits the second voltage to the second electron transport layer, and the second ion transport layer and the second transparent electrode layer respectively transmit a second hole and a second electron under function of the second voltage, and the electrochromic layer changes color under function of the second hole and the second electron;

a value of the second voltage is adjusted to make the electrochromic layer change to be three colors of red, green, blue at different times, and to correspondingly generate red light, green light and blue light with the white light generated by the organic light emitting layer, and the generated red light, green light and blue light are color mixed to be kinds of colors.

Selectively, when a brightness is required to be increased, a time ratio of generating the red light, green light and blue light is unchanged, and light emitting periods of generating the red light, green light and blue light are increased, and when brightness is required to be decreased, the time ratio of generating the red light, green light and blue light is unchanged, and the light emitting periods of generating the red light, green light and blue light are decreased.

Selectively, what the electrochromic layer utilizes is a combination of any one or more of Polythiophene and derivatives thereof, viologen, Tetrathiafulvalene, metallophthalocyanine.

Selectively, the electrochromic layer is formed by any one of etching, deposition, vapor deposition.

Selectively, material of the organic light emitting layer is a combination of any one or more of Polyvinylcarbazole, polyfluorene, Polyphenylene vinylene and Polythiophene.

With implementing the embodiment of the present invention to locate the electrochromic element on the organic electrochromic element to make the electrochromic layer correspondingly change to be three colors of red, green, blue at different times, and to correspondingly generate red light, green light and blue light with the white light generated by the organic light emitting layer. The time ratio of generating the red light, green light and blue light is controlled to mix the red light, green light and blue light in time to generate kinds of colors. In comparison with prior art that three sub pixels of red, green, blue construct one pixel, only the area of one sub pixel is required for the area of one pixel to reduce the ⅔ of the area in the embodiment. The produced flat panel display in the same area can possesses higher resolution to make the images more realistic and more alive.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structure diagram of one embodiment according to the flat panel of the present invention;

FIG. 2 is a specific structure diagram of the flat panel shown in FIG. 1.

FIG. 3 is a sequence diagram when the flat panel of the present invention works.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

Specifically, the terminologies in the embodiments of the present invention are merely for describing the purpose of the certain embodiment, but not to limit the invention. Examples and the appended claims be implemented in the present invention requires the use of the singular form of the book “an”, “the” and “the” are intended to include most forms unless the context clearly dictates otherwise. It should also be understood that the terminology used herein that “and/or” means and includes any or all possible combinations of one or more of the associated listed items.

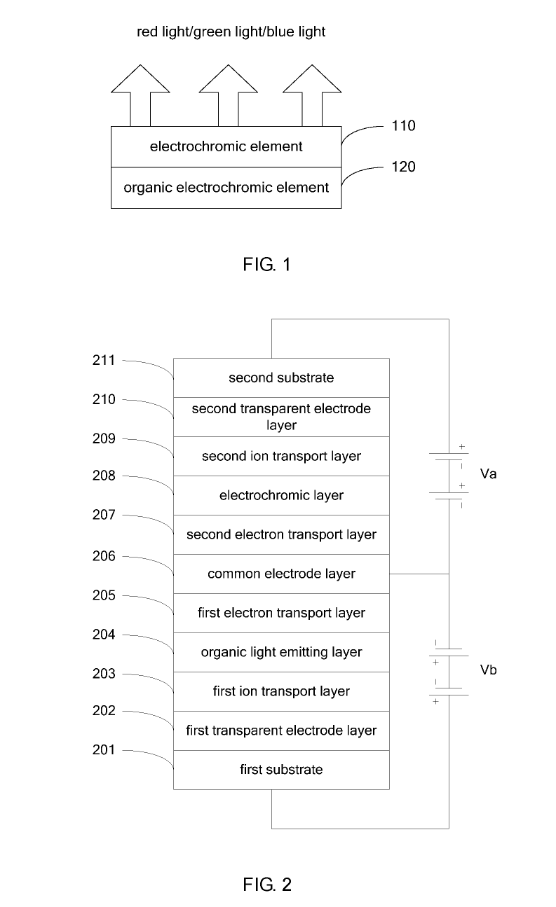

Please refer to FIG. 1 and FIG. 2. FIG. 1 is a structure diagram of a flat panel according to one embodiment of the present invention. FIG. 2 is a specific structure diagram of the flat panel shown in FIG. 1. The flat panel 100 comprises an electrochromic element 110 and an organic electrochromic element 120, and the electrochromic element 110 is located on the organic electrochromic element 120.

A first substrate 201 for supporting, a first transparent electrode layer 202, a first ion transport layer 203, an organic light emitting layer 204, a first electron transport layer 205, a common electrode layer 206 are sequentially stacked up to compose the organic electrochromic element 120. The common electrode layer 206, a second electron transport layer 207, an electrochromic layer 208, a second ion transport layer 209, a second transparent electrode layer 210 and a second substrate 211 for supporting are sequentially stacked up to compose the electrochromic element 110.

The first substrate 201 and the second substrate 211 can be hard material, such as glass or quartz, or can be flexible material, such as flexible polymers, comprising polyethylene naphthalate, polyethylene terephthalate, polyamide, polymethylmethacrylate, polycarbonate and/or polyesteramide.

Material of the first transparent electrode layer 202 and the second transparent electrode layer 210 can be metal oxide or metal oxide containing dopant, such as any one of Indium Tin Oxide, Tin Oxide and F-doped tin oxide. The first transparent electrode layer 202 can be formed on the first substrate 201 by vapor deposition and sputtering. The second transparent electrode layer 210 also can be formed on the second substrate 211 by the same method.

The first ion transport layer 203 and the second ion transport layer 209 can be N,N′-Bis(3-Methylphenyl)-N,N′-bis(phenyl)benzidine, N,N′-Diphenyl-N,N′-tetraphenyl-21H,23H-porphinato. The main chain or the side chain comprises polymer of aromatic tertiary amine, 1,1-Bis[4-[N,N-di(p-toly)amino]phenyl]cyclohexane, N,N′,N″-tri(p-toluidine) and triarylamine derivative, such as 4,4′-methylenebis(N,3-trimethyl-Benzenamine); carbazole derivative, such as N-phenylcarbazole or Poly(N-vinylcarbazole); phthalocyanine derivative, such as nonmetal-phthalocyanine and phthalocyanine blue; starburst amine derivative; enamine (1,2-Ethendiyl)-1,1-bisbenzene derivative; benzene, diethenyl-polymer derivative, such as aromatic tertiary amine; and silane. The first ion transport layer 203 and the second ion transport layer 209 can be formed by spin coating, spray coating, screen printing, inkjet printing.

Material of the organic light emitting layer 204 can be conventional fluorescence and phosphorescence light emitting material, such as Polyvinylcarbazole, polyfluorene, Polyphenylene vinylene and Polythiophene. The organic light emitting layer 204 generates white light under function of the current. The thickness of the organic light emitting layer 204 is 30 to 100 nanometers. When the thickness of the organic light emitting layer 204 is lower than 30 nanometers, the efficiency and the life time is relatively low; when the thickness of the organic light emitting layer is larger than 100 nanometers, the required working voltage is relatively higher. The organic light emitting layer 204 can be formed by kinds of methods, such as vacuum deposition, sputtering, printing, coating, spraying and transcribing.

The first electron transport layer 205 and the second electron transport layer 207 can be uniform, non-microhole thin films which have higher electron mobility, higher glass transition temperature and thermal stability, and can be formed by thermal evaporation, which can be one of oxazole derivative, Porphyrin derivative, phenazine derivative, phenanthroline derivative, heterocyclic compound containing silicon.

The common electrode layer 206 can be low work function metal or alloy, which is one of lithium, pyrope, silver-magnesium alloys, lithium aluminum alloy.

What the electrochromic layer 208 utilizes is a combination of any one or more of Polythiophene and derivatives thereof, viologen, Tetrathiafulvalene, metallophthalocyanine. The electrochromic layer 208 changes color under function of the voltage. The voltage is different, and the generated current is different. The electrochromic layer 208 changes the color correspondingly. For example, at the first value, the electrochromic layer 208 changes to be red; at the second value, it changes to be green; at the third value, it changes to be blue. The electrochromic layer is formed by etching, deposition or vapor deposition.

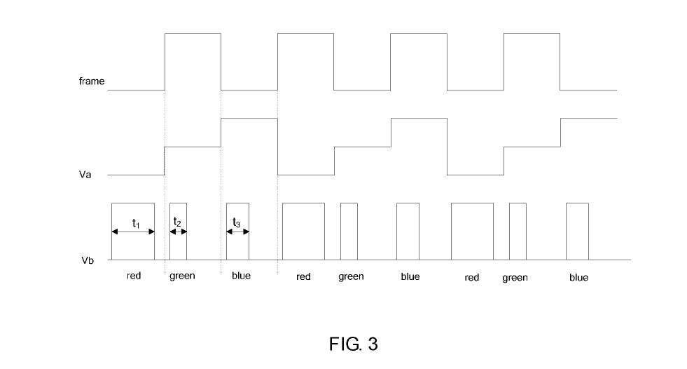

Please combine with FIG. 3. When the flat panel works, in the first frame, the second voltage Va inputted to the electrochromic element is the first value, and the second transparent electrode layer 210 and the common electrode layer 206 respectively generate a second hole and a second electron under function of the second voltage, and the second hole is moved to the electrochromic layer 208 through the second ion transport layer 209, and the second electron is moved to the electrochromic layer 208 through the second electron transport layer 207. In the electrochromic layer 208, the second hole and the second electron are recombined to make the electrochromic layer 208 change to be red.

Meanwhile, the first voltage Vb is inputted to the organic electrochromic element. The first transparent electrode layer 202 and the common electrode layer 206 respectively generate a first hole and a first electron under function of the first voltage. The first hole is moved to the organic light emitting layer 204 through the first ion transport layer 203, and the first electron is moved to the organic light emitting layer 204 through first electron transport layer 205. In the organic light emitting layer 204, the first hole and the first electron are recombined to generate an exciton, and the exciton radiatively decays and emits the white light corresponding to the band gap of the material.

When the white light generated by the organic electrochromic element passes through the electrochromic element changed to be red, most light is filtered, and only the red light can smoothly pass through the electrochromic element to generate the red light.

Similarly, in the second frame, the second voltage Va inputted to the electrochromic element is the second value, and then the electrochromic element changes to be green. When the white light generated by the organic electrochromic element passes through the electrochromic element changed to be green, most light is filtered, and only the green light can smoothly pass through the electrochromic element to generate the green light. In the third frame, the second voltage Va inputted to the electrochromic element is the third value, and then the electrochromic element changes to be blue. When the white light generated by the organic electrochromic element passes through the electrochromic element changed to be blue, most light is filtered, and only the blue light can smoothly pass through the electrochromic element to generate the blue light.

As generating the red light, the green light and the blue light, the on time of the first voltage Vb can be controlled, and thus to change the time lengths t1, t2, t3 of generating the red light, the green light and the blue light. According to the primary principle, the time length ratio t1:t2:t3 of generating the red light, the green light and the blue light is controlled, mixing color in time can be proceeded to generate kinds of colors. As an illustration, when the time length ratio of generating the red light, the green light and the blue light is 1:1:1, the mixed and generated light is white light. When the time length ratio of generating the red light, the green light and the blue light is 1:1:0, the mixed and generated light is yellow light.

When a brightness is required to be increased, a time ratio of generating the red light, green light and blue light is unchanged, and light emitting periods of generating the red light, green light and blue light are increased, and when brightness is required to be decreased, the time ratio of generating the red light, green light and blue light is unchanged, and the light emitting periods of generating the red light, green light and blue light are decreased. As an illustration, when the brightness of the generated white light is required to be increased, the time length ratio of generating the red light, the green light and the blue light is kept to be 1:1:1 and unchanged. The time lengths of generating the red light, the green light and the blue light are correspondingly increased from 0.1 millisecond to 0.2 millisecond. Then, the brightness of the generated white light will be correspondingly increased.

With implementing the embodiment of the present invention to locate the electrochromic element on the organic electrochromic element to make the electrochromic layer correspondingly change to be three colors of red, green, blue at different times, and to correspondingly generate red light, green light and blue light with the white light generated by the organic light emitting layer. The time ratio of generating the red light, green light and blue light is controlled to mix the red light, green light and blue light in time to generate kinds of colors. In comparison with prior art that three sub pixels of red, green, blue construct one pixel, only the area of one sub pixel is required for the area of one pixel to reduce the ⅔ of the area in the embodiment. The produced flat panel display in the same area can possesses higher resolution to make the images more realistic and more alive.

The present invention further provides a flat panel display, comprising a flat panel and a base plate. The flat panel is the flat panel described and shown in FIG. 1 to FIG. 3. The detail specification can be referred from FIG. 1 to FIG. 3 and related descriptions. The repeated description is omitted here.

It is understandable in practical to the person who is skilled in the art that all or portion of the processes in the method according to the aforesaid embodiment can be accomplished with the computer program to instruct the related hardwares. The program can be stored in a readable storage medium if the computer. As the program is executed, the processes of the embodiments in the aforesaid respective methods can be included. The storage medium can be a hardisk, an optical disc, a Read-Only Memory (ROM) or a Random Access Memory (RAM).

Above are embodiments of the present invention, which does not limit the scope of the present invention. Any modifications, equivalent replacements or improvements within the spirit and principles of the embodiment described above should be covered by the protected scope of the invention.

What is claimed is:

1. A flat panel, comprising an electrochromic element and an organic electrochromic element, and the electrochromic element is located on the organic electrochromic element;
a first substrate for supporting, a first transparent electrode layer, a first ion transport layer, an organic light emitting layer, a first electron transport layer, a common electrode layer, which are sequentially stacked up to compose the organic electrochromic element; the common electrode layer, a second electron transport layer, an electrochromic layer, a second ion transport layer, a second transparent electrode layer and a second substrate for supporting, which are sequentially stacked up to compose the electrochromic element;
the flat panel comprises a plurality of pixels, and in each pixel:
a first voltage is applied between the first transparent electrode layer and the common electrode layer, and the first transparent electrode layer transmits the first voltage to the first ion transport layer, and the common electrode layer transmits the first voltage to the first electron transport layer, and the first ion transport layer and the first transparent electrode layer respectively transmit a first hole and a first electron under function of the first voltage, and the organic light emitting layer generates white light under function of the first hole and the first electron;
a second voltage is applied between the second transparent electrode layer and the common electrode layer, and the second transparent electrode layer transmits the second voltage to the second ion transport layer, and the common electrode layer transmits the second voltage to the second electron transport layer, and the second ion transport layer and the second transparent electrode layer respectively transmit a second hole and a second electron under function of the second voltage, and the electrochromic layer changes color under function of the second hole and the second electron;
a value of the second voltage is adjusted to make the electrochromic layer change to be three colors of red, green, blue at different times, and to correspondingly generate red light, green light and blue light with the white light generated by the organic light emitting layer, and the generated red light, green light and blue light are color mixed to be kinds of colors.

2. The flat panel according to claim 1, wherein when a brightness is required to be increased, a time ratio of generating the red light, green light and blue light is unchanged, and light emitting periods of generating the red light, green light and blue light are increased, and when brightness is required to be decreased, the time ratio of generating the red light, green light and blue light is unchanged, and the light emitting periods of generating the red light, green light and blue light are decreased.

3. The flat panel according to claim 1, wherein what the electrochromic layer utilizes is a combination of any one or more of Polythiophene and derivatives thereof, viologen, Tetrathiafulvalene, metallophthalocyanine.

4. The flat panel according to claim 3, wherein the electrochromic layer is formed by any one of etching, deposition, vapor deposition.

5. The flat panel according to claim 1, wherein material of the organic light emitting layer is a combination of any one or more of Polyvinylcarbazole, polyfluorene, Polyphenylene vinylene and Polythiophene.

6. A flat panel display, comprising a flat panel and a base plate, and
the flat panel comprises an electrochromic element and an organic electrochromic element, and the electrochromic element is located on the organic electrochromic element;
a first substrate for supporting, a first transparent electrode layer, a first ion transport layer, an organic light emitting layer, a first electron transport layer, a common electrode layer, which are sequentially stacked up to compose the organic electrochromic element; the common electrode layer, a second electron transport layer, an electrochromic layer, a second ion transport layer, a second transparent electrode layer and a second substrate for supporting, which are sequentially stacked up to compose the electrochromic element;
the flat panel display comprises a plurality of pixels, and in each pixel:
a first voltage is applied between the first transparent electrode layer and the common electrode layer, and the first transparent electrode layer transmits the first voltage to the first ion transport layer, and the common electrode layer transmits the first voltage to the first electron transport layer, and the first ion transport layer and the first transparent electrode layer respectively transmit a first hole and a first electron under function of the first voltage, and the organic light emitting layer generates white light under function of the first hole and the first electron;
a second voltage is applied between the second transparent electrode layer and the common electrode layer, and the second transparent electrode layer transmits the second voltage to the second ion transport layer, and the common electrode layer transmits the second voltage to the second electron transport layer, and the second ion transport layer and the second transparent electrode layer respectively transmit a second hole and a second electron under function of the second voltage, and the electrochromic layer changes color under function of the second hole and the second electron;
a value of the second voltage is adjusted to make the electrochromic layer change to be three colors of red, green, blue at different times, and to correspondingly generate red light, green light and blue light with the white light generated by the organic light emitting layer, and the generated red light, green light and blue light are color mixed to be kinds of colors.

7. The flat panel display according to claim 6, wherein when a brightness is required to be increased, a time ratio of generating the red light, green light and blue light is unchanged, and light emitting periods of generating the red light, green light and blue light are increased, and when brightness is required to be decreased, the time ratio of generating the red light, green light and blue light is unchanged, and the light emitting periods of generating the red light, green light and blue light are decreased.

8. The flat panel display according to claim 6, wherein what the electrochromic layer utilizes is a combination of any one or more of Polythiophene and derivatives thereof, viologen, Tetrathiafulvalene, metallophthalocyanine.

9. The flat panel display according to claim 8, wherein the electrochromic layer is formed by any one of etching, deposition and vapor deposition.

10. The flat panel display according to claim 6, wherein material of the organic light emitting layer is a combination of any one or more of Polyvinylcarbazole, polyfluorene, Polyphenylene vinylene and Polythiophene.
